(19) United States
(12) Patent Application Publication
(10) Pub. No.: US 2007/0120264 A1
(43) Pub. Date: May 31, 2007

(54) A SEMICONDUCTOR HAVING A COPPER-BASED METALLIZATION STACK WITH A LAST ALUMINUM METAL LINE LAYER

(76) Inventors: Matthias Lehr, Dresden (DE); Matthias Schaller, Boxdrof (DE); Tobias Letz, Dresden (DE)

Correspondence Address: WILLIAMS, MORGAN & AMERSON, 10333 RICHMOND, SUITE 1100, HOUSTON, TX, 77042, US

(21) Appl. No.: 11/530,071

(22) Filed: Sep. 8, 2006

(30) Foreign Application Priority Data
Nov. 30, 2005 (DE) 10 2005 057 072.0

(51) Int. Cl. H01L 23/48

(52) U.S. Cl. 257/771

(57) ABSTRACT

By replacing, in an otherwise copper-based metallization stack, copper with aluminum in the very last metal line layer, the respective terminal metal layer of conventional semiconductor devices may be omitted. Consequently, an enormous gain in production cost savings may be achieved, since a plurality of process steps may be omitted, while, on the other hand, substantially no performance degradation may result.

### BACKGROUND OF THE INVENTION

1. Field of the Invention

The present invention generally relates to the formation of integrated circuits, and more particularly, to the fabrication of highly conductive metallization layers based on copper and the connection of the metallization stack with a package or carrier substrate.

2. Description of the Related Art

In modem integrated circuits, a very high number of individual circuit elements, such as transistors, capacitors, resistors and the like, are formed in and on an appropriate substrate, typically in a substantially planar arrangement. The electrical connections between the circuit elements may not be provided within the same level, as usually the number of connections is significantly higher than the number of circuit elements. Consequently, one or more “wiring” levels or layers are provided, which include the metal lines and metal regions, establishing the electrical connections within a specified level and thus may be considered as inner-level connections, and the vias, connecting metal lines or regions in different levels and may therefore be considered as inter-level connections. A wiring layer is typically referred to as a metallization layer, wherein, depending on terminology, a metallization layer may also be understood as containing one layer having formed therein the vias providing the inter-level connection to one adjacent metal line layer.

In this specification, the notion metal line layer will be referred to when a layer of metal lines or regions is considered, and the notion via layer will be used when a layer of vias having contact to an overlying metal line layer or to a lower-lying metal line layer is considered. Consequently, a metallization layer stack may be considered as a wiring network having a lower end in the form of a metal line layer that comprises a complex structure to connect to respective contact plugs directly terminating at circuit elements and having an upper end in the form of a last metal line layer of reduced complexity to provide the electrical connections to the periphery, that is, to a carrier substrate or package. The wiring network with the “intermediate” metal line layers and via layers and the upper and lower contact “ends” thus provides the “fabric” of electrical connections in accordance with the electrical design of the one or more circuits provided in a respective chip.

While aluminum is a well-approved metal in the semiconductor industry, in modern integrated circuits, highly conductive metals such as copper and alloys are increasingly used to accommodate the high current densities encountered during the operation of the devices, as the ongoing reduction of feature sizes also leads to reduced dimensions of the metal lines and vias. Consequently, the metallization layers may comprise metal lines and vias formed from copper or copper alloys, wherein the last metal line layer may provide contact areas for connecting to the solder bumps or bond pads to be formed above the copper-based contact areas.

As previously explained, in manufacturing integrated circuits, it is usually necessary to package a chip and provide leads and terminals for connecting the chip circuitry with the periphery. In some packaging techniques, chips, chip packages or other appropriate units may be connected by means of solder balls, formed from so-called solder bumps, that are formed on a corresponding layer, which will be referred to herein as a contact layer, of at least one of the units, for instance on a dielectric passivation layer of the microelectronic chip. In other techniques, other types of adhesive bumps may be used to directly attach a chip to a package. When a less pronounced complexity of the contacts to the periphery is required and the characteristics of a wire connection is compatible with the application under consideration, the connections to the package may also be established by wire bonding, in which a wire is attached to a bond pad of the chip and to a corresponding terminal of the package. Thus, due to the available infrastructure with respect to bond and test techniques for aluminum-based devices, the last contact pad, also referred to as terminal metal, is typically provided as an aluminum-based metal region. For this purpose, an appropriate barrier and adhesion layer is formed on the copper-based contact area, followed by an aluminum layer. Subsequently, the contact layer including the solder bumps or bond pads is further processed on the basis of the aluminum-covered contact area.

With reference to FIGS. 1a-1b, a typical conventional process flow will now be described to explain the conventional process for providing aluminum bumps or bond pads in a copper-based semiconductor device in more detail.

FIG. 1a schematically shows a semiconductor device 100 that is formed in accordance with a conventional technique, including a metallization layer stack on the basis of copper with a terminal metal comprised of an appropriate barrier material and aluminum. The semiconductor device 100 comprises a substrate 101, which is to represent any appropriate substrate for the formation of circuit elements therein and thereon, wherein, for convenience, any such circuit elements are not shown. Formed above the substrate 101 are one or more metallization layers, including respective via layers and metal line layers, as is explained above. For clarity reasons, a portion of one metallization layer 110 is illustrated in FIG. 1a on which is formed a last metallization layer 120. The metallization layer 110 may comprise a metal line layer of which is shown a metal line 112 that is covered by a dielectric barrier and etch stop layer 111. For example, the metal line 112 may represent a copper-based metal line, which is to be understood as a line, a substantial portion of which is copper. It should be appreciated that other materials may be contained in the metal line 112, such as conductive barrier materials and the like, as well as other metals for forming a copper alloy, for instance at specific areas within the metal line 112, wherein it should be understood that, nevertheless, a significant amount, that is, more than approximately 50 atomic percent, of the material of the line 112 is copper. The barrier and etch stop layer 111 may be comprised of any appropriate dielectric material, such as silicon nitride, silicon carbide, nitrogen-enriched silicon carbide and the like.

The last metallization layer 120 may comprise a last via layer 122 which may comprise an appropriate dielectric material 127, also referred to as interlayer dielectric material (ILD), in which is formed a via 113 that is substantially comprised of copper, wherein, for instance, a conductive barrier layer 125 may provide the required adhesion and diffusion blocking characteristics. Typical materials for the barrier layer 125 are tantalum, tantalum nitride, titanium, titanium nitride and the like. The last metallization layer 120 further comprises a last metal line layer 121, which may comprise an appropriate interlayer dielectric material, such as the material 127, which may be comprised of any appropriate materials, such as silicon dioxide, silicon nitride and the like, wherein, in sophisticated applications, the interlayer dielectric material 127 of the last metal line layer 121 may comprise a low-k dielectric material having a relative permittivity of 3.0 or even less. In the dielectric material 127 is formed a copper-based metal line 124, which may also be separated from the interlayer dielectric material 127 by the barrier layer 125. The last metal line layer 121 may comprise a barrier layer 126, which partially covers the metal line 124 at surface portions that may not be in contact with an overlying terminal metal layer 130. The terminal metal layer 130 may comprise a passivation layer or material 133, such as polyimide or any other appropriate material, such as silicon dioxide-based materials, in which may be formed a conductive terminal metal region 132 which is comprised of aluminum and which is in electrical contact with the metal line 124 and is separated therefrom by a conductive barrier layer 131. The barrier layer 131 may be comprised of any appropriate material that may substantially suppress any inter-diffusion between the metal line 124 and the aluminum region 132. The aluminum region 132 may allow enhanced access for test purposes and may also provide respective contact portions for providing areas above which any solder bumps or bond pads are to be formed so as to connect to a carrier substrate or chip package.

A typical process flow for forming the semiconductor device 100 as shown in FIG. 1a may comprise the following processes. After the formation of any circuit elements and respective metallization layers, the metallization layer 110 may be formed on the basis of well-established single or dual damascene or inlaid techniques, in which a dielectric layer may be deposited first and may be subsequently patterned to receive via openings or trenches, which may then, commonly or separately, be filled with the copper-based material. For example, the metallization layer 110 may be formed by depositing an appropriate dielectric material, such as a low-k dielectric material, which is subsequently patterned to receive first vias and then trenches or to receive first trenches and then vias, which are subsequently coated with an appropriate barrier material, wherein copper may be subsequently filled in by electroplating or any other appropriate deposition technique. In other damascene regimes, a via layer may be formed first and subsequently the interlayer dielectric material may be deposited in an appropriate thickness so as to form therein trenches for receiving the metal line 112.

Thereafter, the barrier layer 111 may be formed on the basis of well-established plasma enhanced chemical vapor deposition (PECVD) techniques. Thereafter, the last metallization layer 120 may be formed. For convenience, in the following process flow, it may be assumed that the via layer 122 and the metal line layer 121 may be formed in accordance with a dual inlaid technique, in which corresponding via openings are formed first and trenches are subsequently etched into the dielectric layer and subsequently the via opening and the trench are filled in a common process sequence. Consequently, the inter-layer dielectric material 127 may be formed on the basis of any appropriate technique, such as PECVD, spin-on techniques, or any combination thereof, wherein, in some regimes, an intermediate etch stop layer may be provided to separate the via layer 122 from the metal line layer 121. In other approaches, the interlayer dielectric layer material 127 may be provided as a substantially continuous layer.

Thereafter, respective via openings may be formed throughout the entire layer 127 by providing a corresponding resist mask and etching through the layer 127, wherein the barrier etch stop layer 111 may be used to reliably stop the corresponding anisotropic etch process. Thereafter, a further resist mask may be formed and corresponding trenches may be etched into the layer 127 in accordance with the dimensions required for the metal line 124. After removal of the resist mask and any other resist material or polymer material required for the second etch step, the etch stop layer 111 may be opened to connect the respective via opening with the underlying metal line 112. Thereafter, the barrier layer 125 may be formed and thereafter copper may be deposited into the respective structure thereby forming the via 123 and the metal line 124 in a common deposition process.

Next, the layer 126 may be deposited on the basis of well-established recipes, followed by the deposition of the layer 133, which may then be patterned to provide the required opening for the terminal metal 132. Thereafter, the conductive barrier layer 131 and an aluminum layer may be deposited and may be patterned in accordance with well-established lithography and etch techniques to form the terminal aluminum region 132 above the last metallization layer 120.

FIG. 1b schematically shows the semiconductor device 100 in accordance with an alternative strategy, in which the aluminum region 132 is embedded in the passivation material 133, except for a required contact area for forming solder bumps thereon or for acting as a bond area. For this purpose, the process sequence may be performed in the same way as described with reference to FIG. 1a, wherein, after the formation of the metal line 124, the barrier layer 131 and an aluminum layer may be deposited and may be patterned in accordance with design requirements. Thereafter, the passivation layer 133 may be deposited and may be patterned to expose required portions of the aluminum region 132.

As previously explained, providing aluminum as the terminal material may offer advantages with respect to test procedures and connecting technologies, since a well-established infrastructure, even for highly complex circuit layouts, is available. On the other hand, a complex process sequence is required for combining copper and aluminum technology for providing respective contact pads for wire bonding or solder bump formation. Consequently, reduced production efficiency and, thus, enhanced production costs may result.

In view of the situation described above, a need exists for a technique that enables a contact technology with reduced complexity.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present invention is directed to providing reduced process complexity during the formation of a copper-based metallization layer stack and a respective contact portion for forming solder bumps thereon or for providing bond pads for wire bonding and other bond techniques. For this purpose, the last metal line layer may be formed of a metal that is compatible with well-approved and available contact technologies so that the conventionally-provided terminal metal layer may be omitted. Consequently, a significant reduction of process complexity, in combination with savings of raw materials and consumables, may be achieved.

According to one illustrative embodiment, a semiconductor device comprises a metallization layer stack comprising copper-based metal line layers and via layers, wherein a last metal line layer formed on a last via layer comprises an aluminum-based metal line.

In another illustrative embodiment of the present invention, a semiconductor device comprises a circuit element and a metallization layer stack electrically connected to the circuit element. The metallization layer stack comprises a last via layer having a via that is substantially comprised of a first metal. Moreover, the metallization layer stack further comprises a last metal line layer having a metal line that is substantially comprised of a second metal other than the first metal.

According to yet another illustrative embodiment of the present invention, a method comprises forming a last via layer of a copper-based metallization layer stack of a semiconductor device by forming a via opening in an interlayer dielectric layer and filling the via opening with a copper-containing material to form a via. Moreover, the method comprises forming a metal line on the last via layer, wherein the metal line connects to the via and comprises aluminum.

### BRIEF DESCRIPTION OF THE DRAWINGS

The invention may be understood by reference to the following description taken in conjunction with the accompanying drawings, in which like reference numerals identify like elements, and in which:

FIGS. 1a-1b schematically show cross-sectional views of a conventional semiconductor device including a copper-based metallization layer stack with a terminal metal comprised of aluminum that is formed above the last metal line layer; and

FIGS. 2a-2h schematically show cross-sectional views of a semiconductor device comprising a copper-based metallization layer stack, in which the last metal line layer is formed of an aluminum-based metal, according to illustrative embodiments of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present invention is directed to reducing the process complexity and the overall production costs of highly complex integrated circuits having a copper-based metallization layer stack, in that the last metal line layer is formed on the basis of a metal that allows a high degree of compatibility with existing contact technologies, wherein, on the other hand, a significant reduction in the number of process steps may be achieved during the formation of contact pads that may be used for the formation of solder bumps or which may act as bond pads for other bond technologies. As previously explained, aluminum is a well-approved terminal metal which may allow superior handling and processing during test procedures and may be efficiently used for the formation of bond pads and contact portions for further bump formation. Consequently, by using an aluminum-based metal as the material for the last metal line layer, the corresponding terminal metal layer, typically provided in conventional devices, may be omitted, thereby significantly saving on process complexity and raw materials. Consequently, in some illustrative embodiments, the last via layer may be formed of vias that may be substantially comprised of copper, while the last metal lines connected thereto may be formed of metal lines that are substantially comprised of aluminum. In this respect, it should be appreciated that the term “substantially comprised of copper or aluminum” is to be understood as to describe a material that contains copper or aluminum as the major portion thereof and, thus, includes at least more than approximately 50 atomic percent copper or aluminum. Similarly, the terms “copper-based” or “aluminum-based” as used in the specification, are meant to describe materials or layers in which the respective metals or conductive portions are substantially comprised of copper or aluminum. Consequently, the present invention provides a technique that results in a significant cost reduction, since the well-known aluminum may be maintained as the interface material for testing of the devices and for assembling the same by any appropriate technique, such as direct bonding on the basis of solder bumps or by wire bond techniques and the like. At the same time, a complete mask layer may be omitted, which significantly reduces process steps, process time, tool time, cycle time, and the costs of raw materials and consumables.

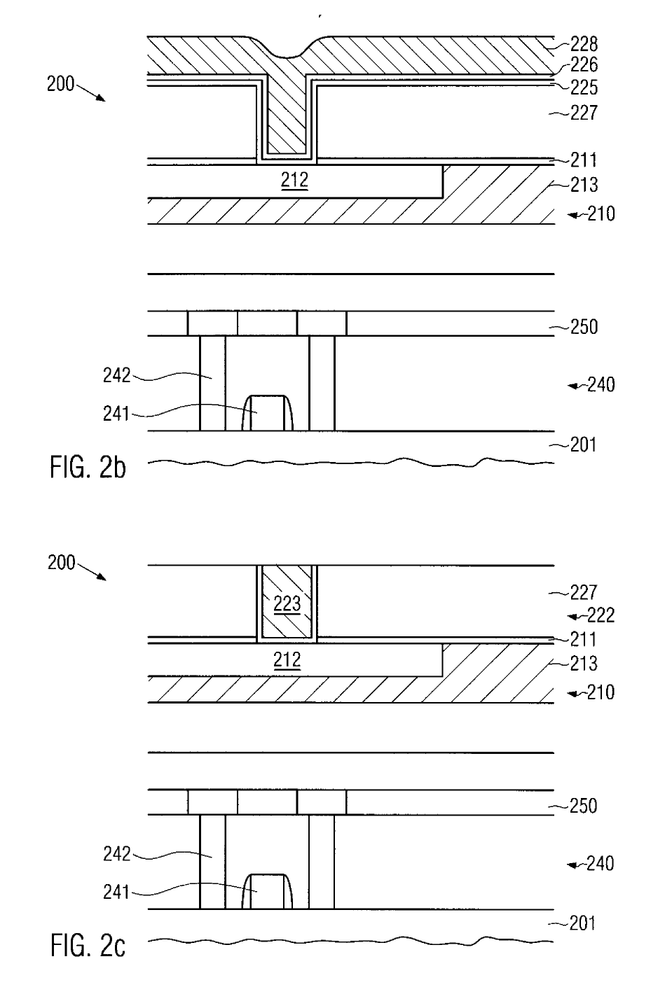

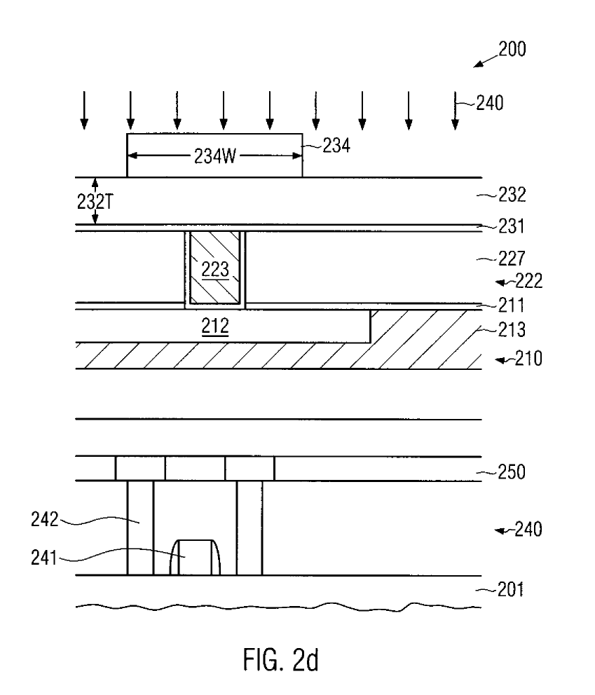

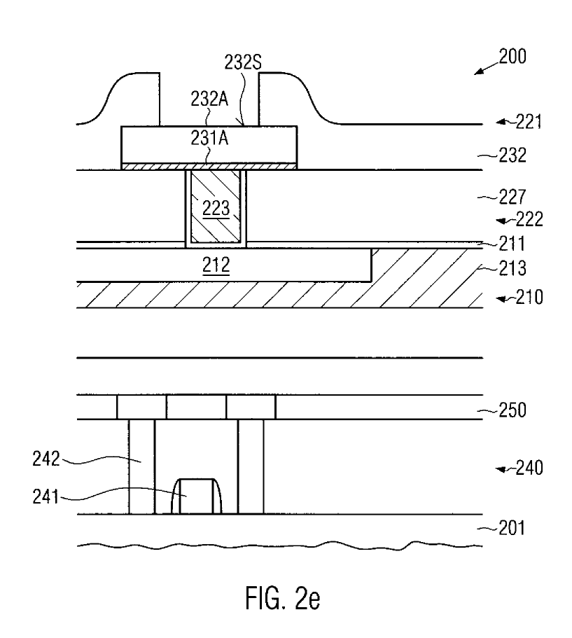

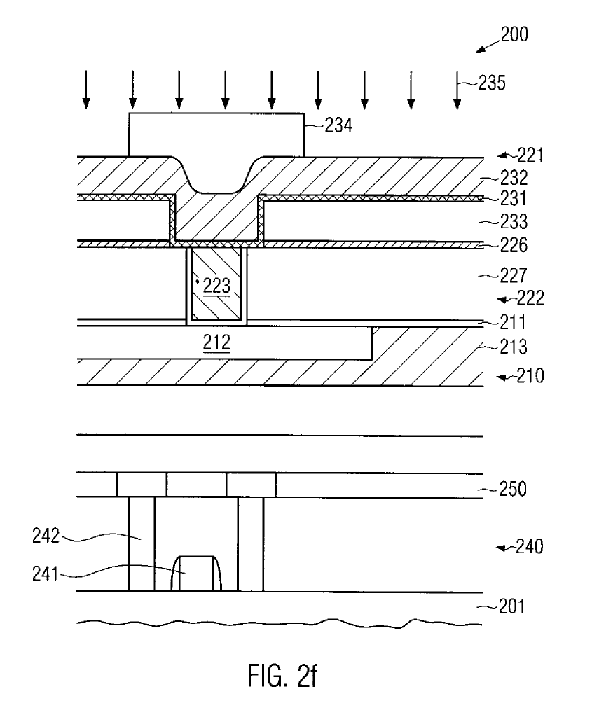

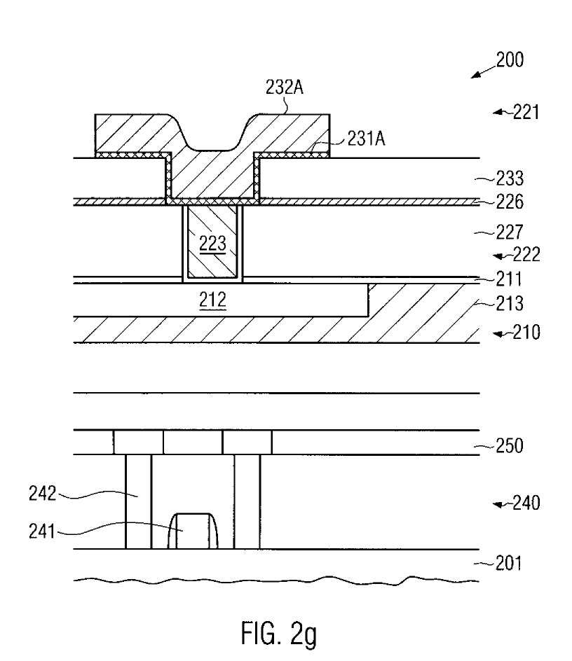

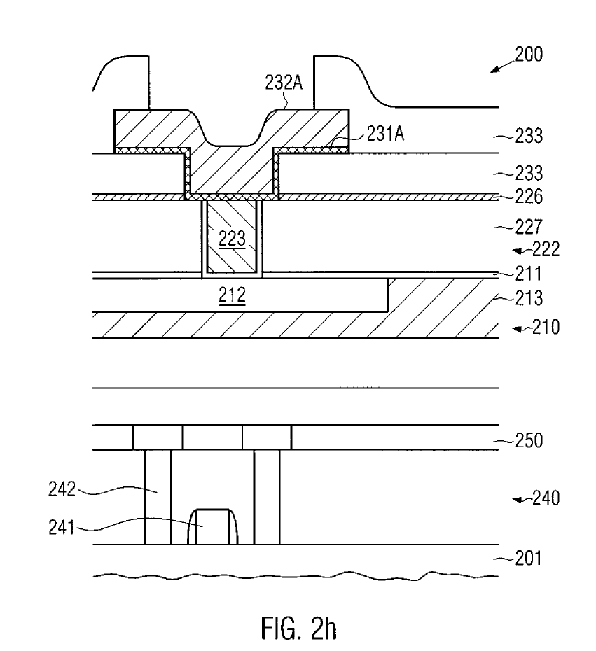

With reference to FIGS. 2a-2h, further illustrative embodiments of the present invention will now be described in more detail. FIG. 2a schematically illustrates a cross-sectional view of a semiconductor device 200 which may comprise a substrate 201 that represents any appropriate substrate for the formation of semiconductor devices. For example, the substrate 201 may represent a bulk silicon substrate, a silicon-on-insulator (SOI) substrate, a germanium substrate, or any other appropriate carrier material for having formed thereon respective crystalline or amorphous semiconductor layers for fabricating circuit elements, such as transistors, capacitors, resistors and the like. Consequently, the semiconductor device 200 may have formed in and on the substrate 201 a device layer 240 which may include a plurality of circuit elements, such as transistors and the like, which are indicated by reference numeral 241, representing in the present example a field effect transistor having, in some illustrative embodiments, a gate length of approximately 100 nm and less or even of 50 nm and even less. The device layer 240 may further comprise respective contact plugs 242, which may be in direct contact with the respective portions of the circuit elements 241.

The semiconductor device 200 may further comprise a first metallization layer 250 that may represent a first metal line layer including a plurality of metal lines which are directly connected to respective contact plugs 242 according to the specified circuit layout. The metallization layer 250 may represent a copper-based metallization layer, that is, respective metal lines therein may be substantially comprised of copper. Moreover, the semiconductor device 200 further comprises a further metallization layer 210, which may comprise an interlayer dielectric layer 213, in which is formed a copper-based metal line 212. Moreover, the metallization layer 210 may further comprise a dielectric barrier/etch stop layer 211, which may suppress any inter-diffusion between an overlying dielectric layer 227 and the copper-based material in the line 212. Moreover, the barrier/etch stop layer 211 may exhibit a high etch selectivity with respect to an anisotropic etch process for patterning the dielectric layer 227 in a subsequent etch process. For example, the barrier/etch stop layer 211 may be comprised of silicon nitride, silicon carbide, nitrogen-enriched silicon carbide and the like. It should be appreciated that, in other embodiments, the barrier/etch stop layer 211 may be omitted or may be replaced by other materials that may provide the desired characteristics. For example, in some embodiments, it may be considered appropriate to form a corresponding conducting surface layer within the metal line 212 which may exhibit a high resistance against moisture diffusion and oxygen diffusion or diffusion of other unwanted materials that may readily react with copper. For example, an appropriate copper alloy or other conductive material or dielectric material may be provided on top of the metal line 212.

The dielectric material of the layer 213 may represent any appropriate dielectric material, such as silicon dioxide, fluorine-doped silicon dioxide, or may be comprised of a low-k dielectric material, wherein the dielectric constant thereof may be as low as 3.0 or even less. Similarly, the dielectric layer 227, which is to receive vias for forming the last via layer of the semiconductor device 200, may be comprised of any appropriate dielectric material, such as, for instance, fluorine-doped silicon dioxide, silicon dioxide, or even a low-k dielectric material.

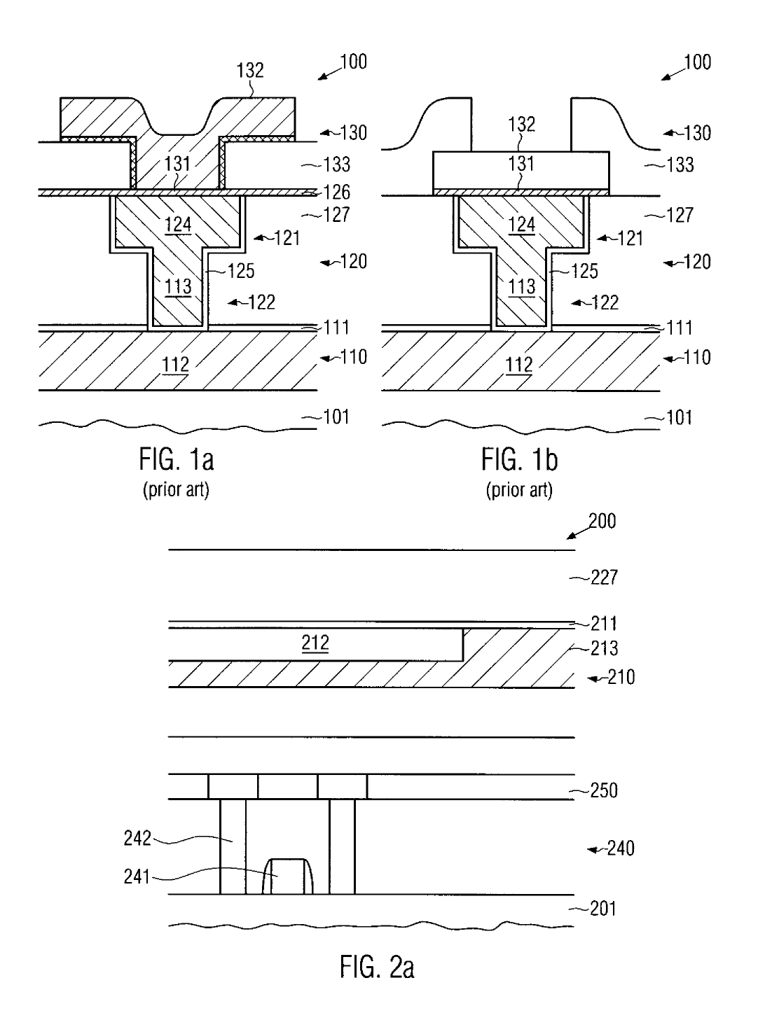

A typical process flow for forming the semiconductor device 200 as shown in FIG. 2a may comprise the following processes and may also include similar processes as are already explained with reference to FIGS. 1a-1b. That is, the device layer 240 may be formed on the basis of well-established recipes, wherein design rules for the circuit elements 241 may dictate critical dimensions as small as 100 nm and less or even 50 nm and less. After the formation of the device layer 240, the metallization layer 250 may be formed on the basis of well-established inlaid techniques, including the patterning of the dielectric material and filling of respective trenches with a copper-based metal. Depending on the device requirements, a plurality of metallization layers may be formed and finally the last-but-one metallization layer 210 may be formed on the basis of established recipes by depositing the layer 213 by any appropriate technique and subsequently patterning the same on the basis of advanced photolithography and anisotropic etch techniques, wherein a dual inlaid technique or a single inlaid technique may be used. After filling in the copper-based metal for forming the metal line 212, any excess material, such as excess copper and excess barrier material (not shown), may be removed by electrochemical polishing, chemical mechanical polishing (CMP) and the like. Thereafter, the barrier/etch stop layer 211, if provided, may be formed by well-established deposition techniques. Next, the dielectric layer 227 may be deposited, for instance, by PECVD. Thereafter, the dielectric layer 227 may be patterned on the basis of photolithography and anisotropic etch techniques to etch through the dielectric layer 227 and subsequently opening the etch stop layer 211 for providing a direct connection to the metal line 212. Next, a conductive barrier layer and a seed layer may be deposited in order to prepare the device 200 for the deposition of a copper-based metal.

FIG. 2b schematically shows the semiconductor device 200 after the completion of the above-described process sequence and after the electrochemical deposition of a copper-based layer 228, which may be formed on a seed layer 226, which, in turn, may be formed on an appropriate barrier layer 225. Thereafter, the excess material, i.e., the excess material of the layer 228 and of the layers 226 and 225, may be removed by, for instance, CMP, possibly in combination with electrochemical etch techniques, thereby providing a planarized surface typography.

FIG. 2c schematically illustrates the device 200 after the above-described process sequence. Hence, the device 200 comprises a via 223 that is substantially comprised of copper, wherein it should be understood that, according to the above-given definition, the via 223 may comprise other materials, such as the barrier material 225. Consequently, the via 223 in combination with the dielectric material of the layer 227 represents the last via layer 222.

FIG. 2d schematically illustrates the semiconductor device 200 in a further advanced manufacturing stage. A metal layer 232, which is comprised of a metal other than copper, is formed above the last via layer 222 and may be separated therefrom by a conductive barrier layer 231. In one illustrative embodiment, the metal layer 232 represents an aluminum-based layer, wherein it should be appreciated that other materials may be contained in the layer 232, as long as the essential portion of the layer 232 is aluminum. Moreover, a resist mask 234 is formed above the metal layer 232, possibly in combination with any anti-reflective coating (ARC) layers in accordance with well-established process techniques. Moreover, the semiconductor device 200 is subjected to an anisotropic etch process 240 for patterning the layers 232 and 231.

The device 200 as shown in FIG. 2d may be formed according to the following processes. The conductive barrier layer 231 may be formed in accordance with well-established techniques, wherein any appropriate material, such as tantalum, tantalum nitride, tungsten nitride and the like, may be formed on the dielectric material 227 and the exposed via 223. It should be appreciated that the barrier layer 231 may be omitted or may be formed in accordance with other techniques, for instance, by locally forming the layer 231 on an exposed surface portion of the via 223 by electrochemical deposition techniques and the like. Thereafter, the metal layer 232 may be deposited on the basis of well-established recipes. In some illustrative embodiments, the design of the semiconductor device 200 may be reconfigured prior to the formation of the device 200 so as to first determine a desired target resistivity of a last metal line to be formed on the basis of the metal layer 232 in order to determine respective target dimensions of the metal line to be formed from the layer 232. For example, the target dimensions may be directly taken from a corresponding copper-based metallization scheme as is, for instance, described with reference to FIGS. 1a-1b. Thus, substantially the same dimensions may be used for a metal line formed on the basis of the layer 232 as is, for instance, shown for the copper-based metal line 124. In this respect, it should be appreciated that a slight decrease in performance of the respective metal line, owing to the reduced conductivity of aluminum compared to copper, may be readily tolerated, since the last metal line is typically a very thick and broad line. Consequently, a slight decrease of the conductivity may not unduly affect the overall performance of the device 200.

In other illustrative embodiments, for a desired low target resistivity, corresponding width and/or depth dimensions may be established, and the layout of the device 200 may be accordingly re-designed so as to take into consideration the respectively determined target values. For instance, a width 234W of the resist mask 234 may be adjusted on the basis of a respective target dimension and/or a thickness 232T of the aluminum layer 232 may be appropriately selected on the basis of a respective target value. A corresponding increase in width according to the target value 234W may typically be acceptable, since the distance of neighboring metal lines in the last metal line layer is typically not a critical parameter. On the other hand, the depth of the respective metal line, that is, the thickness 232T, may typically be increased without any further negative impact, when the width 234W may not be increased in a desired manner.

During the anisotropic etch process 240 on the basis of well-established etch chemistries, the layers 232 and 231 may be patterned and subsequently a passivation material may be formed so as to substantially enclose the resulting metal line.

FIG. 2e schematically illustrates the semiconductor device 200 after the completion of the above-described process sequence. Hence, the device 200 comprises a last metal line layer 221, represented by an aluminum-based metal line 232A that is separated from the underlying last via layer 222 by the patterned barrier layer 231A, and a passivation layer 232, which, in turn, may be patterned so as to expose a surface portion 232S of the metal line 232A. The passivation layer 232 may be comprised of any appropriate passivation material, such as polyimide, a silicon dioxide-based material, and the like. The passivation layer 232 may be patterned in accordance with defined requirements such that the exposed surface portion 232S may be appropriate for receiving corresponding solder bumps, when the device 200 is to be attached to a package or carrier substrate on the basis of a reflow technique, while, in other cases, the surface portion 232S may represent a bond pad. Moreover, in this stage of manufacture, the surface portion 232S is accessible by any test instrument, as is typically available for test procedures that may be performed in a similar way with conventional devices, such as the semiconductor device 100 as shown in FIG. 1b.

FIG. 2f schematically shows the semiconductor device 200 in accordance with other illustrative embodiments, in which a passivation scheme is illustrated that substantially corresponds to the arrangement shown in FIG. 1a. In this case, the semiconductor device 200 may comprise in this manufacturing stage a patterned passivation layer 233, which may represent the dielectric material of the last metal line layer 221, wherein, in a corresponding opening of the passivation layer 233, an appropriate conductive barrier layer 231 may be formed so as to avoid direct contact of the via 223 with the overlying aluminum-based metal layer 232. Moreover, an appropriate resist mask 234 may be formed above the aluminum-based layer 232, wherein, with respect to the width dimension of the resist mask 234 and the thickness of the layer 232, the same criteria apply as previously explained with reference to FIG. 2e. Furthermore, the device 200 may be subjected to an appropriately designed etch process 235 for selectively removing exposed portions of the metal layer 232 and the conductive barrier layer 231. The etch process 235 may be based on well-established recipes, which may also be used during the formation of the conventional devices, such as the device shown in FIG. 1a. Moreover, as previously explained with reference to FIGS. 2d-2e, in this case also, the conductive barrier layer 231 may, in some embodiments, be omitted, wherein the exposed surface portion of the via 223 may be correspondingly modified so as to exhibit the desired characteristics with respect to its diffusion blocking capability and its electric conductivity, or when a corresponding barrier layer may be formed in a highly localized manner, as has been previously explained.

For forming the semiconductor device 200 as shown in FIG. 2f, well-established techniques may be used similarly as for the conventional device 100 of FIG. 1a.

FIG. 2g schematically shows the semiconductor device 200 after the completion of the etch process 235 and the removal of the resist mask 234. Consequently, the device 200 comprises the last metal line 232A formed on the respectively patterned barrier layer 231A, if provided, thereby defining the completed last metal line layer 212. Thus, a passivation scheme is obtained in which the aluminum-based metal, i.e., the region 232A, partially extends above the passivation material 233 and covers a portion thereof.

FIG. 2h schematically illustrates the semiconductor device 200 in accordance with another illustrative embodiment, in which a passivation scheme is realized for providing the passivation material below and above the aluminum-based metal line 232A. In order to provide the configuration as shown in FIG. 2h, any well-established passivation scheme may be used, for instance, by forming an additional passivation layer above the semiconductor device 200 as shown in FIG. 2g and subsequently patterning the additional passivation material on the basis of target values for the dimensions of the size of the surface portion 232S that is to be exposed for the further processing of the device 200.

Irrespective of the passivation scheme used, the device 200 may then be subjected to any test procedures and/or the further processing may advance to the formation of corresponding under-bump metallization layers followed by respective solder bumps, wherein the device 200 is to be connected to a corresponding carrier substrate or a package by a corresponding reflow technique for directly contacting respective contact pads on the carrier substrate or package. In other techniques, the exposed surface portions 232S may be used as bond pads, or respective bond pads may be formed thereon, depending on the technology used.

As a result, the present invention provides a semiconductor device and a manufacturing process therefor, in which a significant improvement with respect to process complexity and, thus, production cost, may be achieved for sophisticated semiconductor devices requiring a copper-based metallization scheme. For this purpose, the conventionally provided terminal metal layer may be omitted, in that the last metal line layer is formed on the basis of an appropriate metal which may avoid the disadvantages of the highly conductive copper, such as oxidation and corrosion, wherein copper may nevertheless represent the essential component of the metal lines and vias in the remaining metallization layer stack. In one illustrative embodiment, aluminum is used as the main component of the metal line in the last metal line layer so that a terminal metal layer may be omitted, while still providing the advantages associated with the provision of aluminum as a contact material for test procedures and the formation of bond pads and bump structures. As previously explained, even with non-amended semiconductor designs, a significant negative influence on device performance may be avoided, since the overall dimensions of the very last metal line may typically provide for a low resistance, thereby reducing the difference between aluminum and copper in their respective performance during the operation of the device. In other cases, the corresponding dimensions of the last metal lines may be re-designed so as to take into consideration the reduced conductivity of aluminum with respect to copper, which may be achieved by correspondingly increasing the width of the metal lines and/or the height thereof, wherein typically at least one of these dimensions may be altered while maintaining compatibility to the remaining design of the semiconductor devices. Due to the omission of the terminal metal layer by replacing copper with aluminum in the very last metal line layer, significant cost savings, due to reduced process complexity, cycle time, tool time and the like, may be achieved. For example, in a process regime in which a single-inlaid process technique is used for the formation of the remaining copper-based metallization layer stack, that is, in a process scheme in which respective via layers and metal line layers are formed independently of each other, the present invention may reduce the process complexity by rendering obsolete one ILD deposition process, a lithography process, a corresponding etch process including any clean processes, a barrier and seed layer deposition process, a copper plating process and a subsequent chemical mechanical polishing process for removing the excess material. Also, in a dual inlaid scheme, in which corresponding via layers and metal line layers are formed in an interrelated process, wherein at least the filling in of the metal is performed in a common deposition process, an ILD deposition process, that is, the deposition of an upper part thereof, may be omitted, and also a lithography process, a subsequent etch process including respective cleaning processes, may be saved. As a consequence, in any case, a significant improvement may be obtained with only minor or no performance degradation.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A semiconductor device, comprising:
a metallization layer stack comprising copper-based metal line layers and via layers, a last metal line layer formed on a last via layer comprising an aluminum-based metal line.

2. The semiconductor device of claim 1, wherein a said last via layer of said metallization layer stack comprises a copper-based via in contact with said aluminum-based metal line.

3. The semiconductor device of claim 1, wherein a portion of said metal line is provided so as to act as a contact pad for receiving one of a bond wire and a solder bump.

4. The semiconductor device of claim 1, further comprising a passivation layer formed adjacent to said metal line of said last metal line layer so as to expose a surface portion of said metal line for receiving one of a connecting bump and a bond wire.

5. The semiconductor device of claim 4, wherein said passivation layer is formed at least partially above said metal line of said last metal line layer.

6. The semiconductor device of claim 4, wherein said passivation layer is formed at least partially below said metal line of said last metal line layer.

7. The semiconductor device of claim 4, wherein said passivation layer is formed at least partially below and above said metal line of said last metal line layer.

8. The semiconductor device of claim 2, further comprising a conductive barrier layer formed between said last via and said metal line of the last metal line layer.

9. The semiconductor device of claim 2, wherein a surface of said via in the last via layer that is in contact with said metal line comprises a copper alloy.

10. A semiconductor device, comprising:
a circuit element; and
a metallization layer stack electrically connected to said circuit element and comprising a last via layer having a via substantially comprised of a first metal, said metallization layer stack further comprising a last metal line layer having a metal line substantially comprised of a second metal other than said first metal.

11. The semiconductor device of claim 10, wherein a surface portion of said metal line represents a contact pad for receiving a connecting structure for contact to a package.

12. The semiconductor device of claim 11, wherein said first metal is copper.

13. The semiconductor device of claim 11, wherein said second metal is aluminum.

14. The semiconductor device of claim 11, wherein said last via layer comprises an interlayer dielectric material and said last metal line layer comprises a passivation material that is different to said interlayer dielectric material.

15. The semiconductor device of claim 14, wherein said metal line is embedded in said passivation material except for a contact portion.

16. The semiconductor device of claim 14, wherein at least a portion of said metal line extends above said passivation material.

17. The semiconductor device of claim 10, further comprising a conductive barrier region formed between said via and said metal line.

18. A method, comprising:
forming a last via layer of a copper-based metallization layer stack of a semiconductor device by forming a via opening in an interlayer dielectric layer and filling said via opening with a copper-containing material to form a via; and
forming a metal line on said last via layer, said metal line connecting to said via and comprising aluminum.

19. The method of claim 18, further comprising determining a target resistivity of said metal line and target dimensions thereof on the basis of said target resistivity prior to forming said last via layer, and forming said metal line on the basis of said target dimensions.

20. The method of claim 18, further comprising defining a surface portion on said metal line to act as a contact pad for connecting to a package.
